(19) United States
(12) Patent Application Publication
(10) Pub. No.: US 2024/0072093 A1
(43) Pub. Date: Feb. 29, 2024

(54) SOLID-STATE IMAGING ELEMENT AND IMAGING DEVICE

(71) Applicant: SONY SEMICONDUCTOR SOLUTIONS CORPORATION, KANAGAWA (JP)

(72) Inventors: SHINICHI MIYAKE, KANAGAWA (JP); KAZUYUKI TOMIDA, KANAGAWA (JP); ATSUMI NIWA, KANAGAWA (JP)

(21) Appl. No.: 18/259,590

(22) PCT Filed: Dec. 20, 2021
(86) PCT No.: PCT/JP2021/046913

§ 371 Date: Jun. 28, 2023

(30) Foreign Application Priority Data
Jan. 6, 2021 (JP) 2021-000673

(51) Int. Cl. H01L 27/146; H01L 23/00; H04N 25/77

(52) U.S. Cl. CPC H01L 27/14634; H01L 24/08; H01L 27/14627; H01L 27/14636; H04N 25/77; H01L 2224/08146; H04N 25/47

(57) ABSTRACT

A solid-state imaging element (200) according to the present disclosure includes a light receiving substrate (201) and a circuit board (202). The light receiving substrate (201) includes a plurality of light receiving circuits (211) in which photoelectric conversion elements are provided. The circuit board (202) is bonded to the light receiving substrate (201) and includes a plurality of address event detection circuits (231) that respectively detects voltage changes output from the photoelectric conversion elements of the plurality of light receiving circuits (211). The circuit board (202) includes a first element region (501) and a second element region (502). In the first element region (501), a first transistor (T1) driven by a first voltage (VDD1) is arranged. In the second element region (502), a second transistor (T2) driven by a second voltage (VDD2) lower than the first voltage (VDD1) is arranged. A full trench isolation (FTI) structure (521) is arranged between the first element region (501) and the second element region (502) adjacent to each other.

### FIELD

The present disclosure relates to a solid-state imaging element and an imaging device.

### BACKGROUND

In recent years, an asynchronous solid-state imaging element in which an address event detection circuit that detects, for each pixel address, that a light quantity of a pixel exceeds a threshold as an address event in real time is provided for each pixel has been proposed (see, for example, Patent Literature 1).

### CITATION LIST

### Patent Literature

Patent Literature 1: JP 2016-533140 A

### SUMMARY

### Technical Problem

However, in the above-described conventional technology, it is difficult to reduce a pixel area in such an asynchronous solid-state imaging element.

Thus, the present disclosure proposes a solid-state imaging element and an imaging device in which a pixel area can be reduced.

### Solution to Problem

According to the present disclosure, there is provided a solid-state imaging element. The solid-state imaging element includes a light receiving substrate and a circuit board. The light receiving substrate includes a plurality of light receiving circuits in which photoelectric conversion elements are provided. The circuit board is bonded to the light receiving substrate and includes a plurality of address event detection circuits that respectively detects voltage changes output from the photoelectric conversion elements of the plurality of light receiving circuits. The circuit board includes a first element region and a second element region. In the first element region, a first transistor driven by a first voltage is arranged. In the second element region, a second transistor driven by a second voltage lower than the first voltage is arranged. A full trench isolation (FTI) structure is arranged between the first element region and the second element region adjacent to each other.

### BRIEF DESCRIPTION OF DRAWINGS

FIG. 1 is a block diagram illustrating one configuration example of an imaging device according to an embodiment of the present disclosure.

FIG. 2 is a view for describing a stacked structure of a solid-state imaging element according to the embodiment of the present disclosure.

FIG. 3 is a view for describing a plane configuration of a light receiving substrate according to the embodiment of the present disclosure.

FIG. 4 is a view for describing a plane configuration of a circuit board according to the embodiment of the present disclosure.

FIG. 5 is a view for describing a configuration of an effective pixel according to the embodiment of the present disclosure.

FIG. 6 is a view illustrating a circuit configuration of the effective pixel according to the embodiment of the present disclosure.

FIG. 7 is a view for describing the configuration of the effective pixel according to the embodiment of the present disclosure.

FIG. 8 is a view illustrating a cross-sectional configuration of the solid-state imaging element according to the embodiment of the present disclosure.

FIG. 9 is a view illustrating a plane configuration of the solid-state imaging element according to the embodiment of the present disclosure.

FIG. 10 is a view illustrating a cross-sectional configuration of the solid-state imaging element according to the embodiment of the present disclosure.

FIG. 11 is a view illustrating a cross-sectional configuration of a solid-state imaging element in a reference example of the present disclosure.

FIG. 12 is a view illustrating a cross-sectional configuration of a solid-state imaging element according to a first modification example of the embodiment of the present disclosure.

FIG. 13 is a view illustrating a cross-sectional configuration of a solid-state imaging element according to a second modification example of the embodiment of the present disclosure.

FIG. 14 is a view illustrating a cross-sectional configuration of a solid-state imaging element according to a third modification example of the embodiment of the present disclosure.

FIG. 15 is a view illustrating a cross-sectional configuration of a solid-state imaging element according to a fourth modification example of the embodiment of the present disclosure.

FIG. 16 is a view illustrating a cross-sectional configuration of a solid-state imaging element according to a fifth modification example of the embodiment of the present disclosure.

FIG. 17 is a view illustrating a cross-sectional configuration of a solid-state imaging element according to a sixth modification example of the embodiment of the present disclosure.

FIG. 18 is a view illustrating a cross-sectional configuration of a solid-state imaging element according to a seventh modification example of the embodiment of the present disclosure.

FIG. 19 is a view illustrating a circuit configuration of an effective pixel according to an eighth modification example of the embodiment of the present disclosure.

FIG. 20 is a block diagram illustrating a second configuration example of an address event detection unit.

FIG. 21 is a block diagram illustrating an example of a configuration of an imaging device according to a second configuration example, that is, a scanning type imaging device used as an imaging device in an imaging system to which a technology according to the present disclosure is applied.

FIG. 22 is a schematic diagram illustrating an example of a configuration of a ranging system according to the embodiment of the present disclosure.

FIG. 23 is a block diagram illustrating an example of a circuit configuration.

### DESCRIPTION OF EMBODIMENTS

In the following, each of embodiments of the present disclosure will be described in detail on the basis of the drawings. Note that in each of the following embodiments, overlapped description is omitted by assignment of the same reference sign to the same parts.

Conventionally, a synchronous solid-state imaging element that captures image data (frame) in synchronization with a synchronization signal such as a vertical synchronization signal has been used in an imaging device or the like. In this general synchronous solid-state imaging element, image data can be acquired only in each cycle of a synchronization signal (such as 1/60 seconds), and thus it is difficult to deal with a case where processing with higher speed is required in fields related to traffic, a robot, and the like.

Thus, an asynchronous solid-state imaging element in which an address event detection circuit that detects, for each pixel address, that a light quantity of the pixel exceeds a threshold as an address event in real time is provided for each pixel has been proposed. In this solid-state imaging element, a photodiode and a plurality of transistors to detect the address event are arranged for each pixel.

However, in the above-described conventional technology, since it is difficult to reduce an area of the address event detection circuit arranged for each pixel, it is difficult to reduce an area of a pixel arranged at the same position as the address event detection circuit in plan view.

This is because it is difficult to reduce an area of an isolation region that electrically isolates a region where a transistor driven by a high voltage is arranged and a region where a transistor driven by a low voltage is arranged in the address event detection circuit.

Thus, it is expected to realize a technology capable of overcoming the above-described problems and reducing a pixel area.

[Configuration of an Imaging Device]

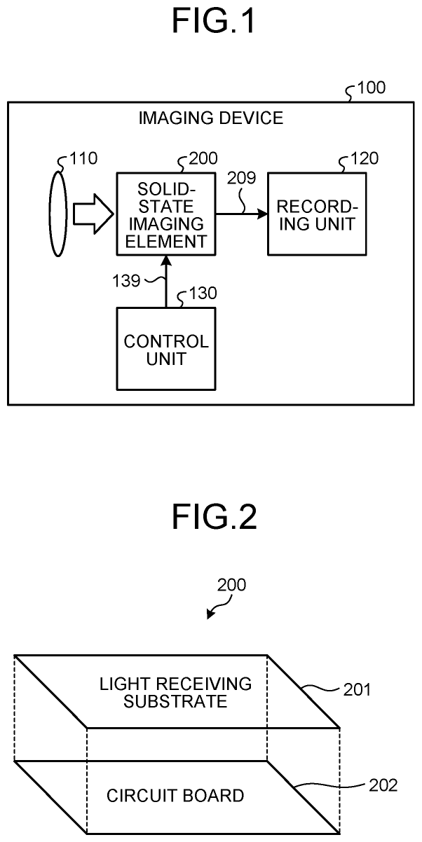

First, a configuration of an imaging device 100 according to an embodiment will be described with reference to FIG. 1. FIG. 1 is a block diagram illustrating one configuration example of the imaging device 100 according to the embodiment of the present disclosure.

The imaging device 100 according to the embodiment includes a lens 110, a solid-state imaging element 200, a recording unit 120, and a control unit 130. As the imaging device 100, a camera mounted on a wearable device, an in-vehicle camera, or the like is assumed.

The lens 110 captures incident light from a subject and forms an image on an imaging surface of the solid-state imaging element 200.

The solid-state imaging element 200 is also referred to as an event-based vision sensor (EVS), and detects, for each of a plurality of pixels, that an absolute value of a change amount in luminance exceeds a threshold as an address event. The address event includes, for example, an on-event indicating that the amount of increase in luminance exceeds the upper limit threshold and an off-event indicating that an amount of decrease in the luminance falls below a lower limit threshold smaller than the upper limit threshold.

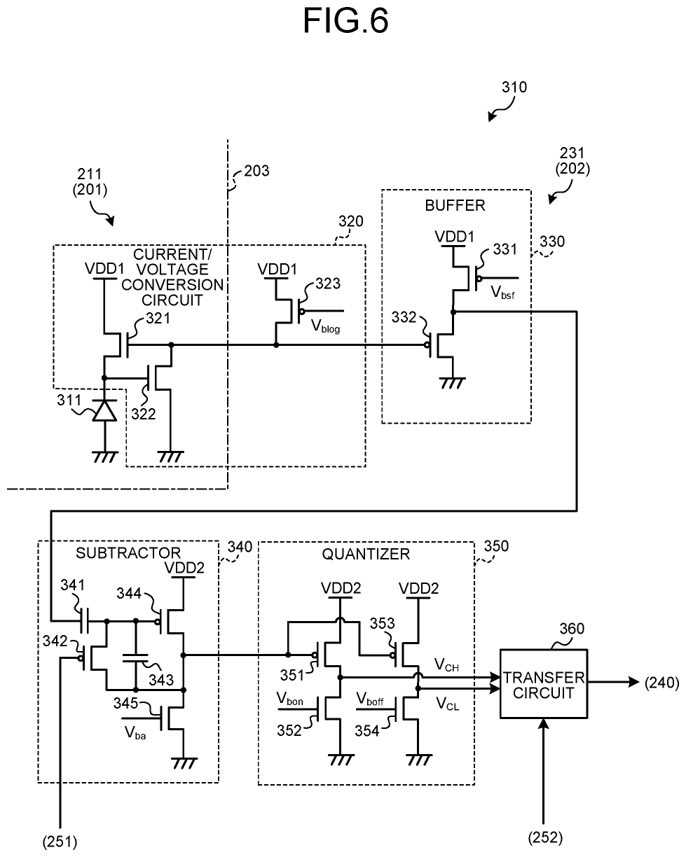

Then, the solid-state imaging element 200 generates, for each pixel, a detection signal indicating a detection result of the address event. Each of the detection signals includes an on-event detection signal V_{CH} (see FIG. 6) indicating presence or absence of the on-event and an off-event detection signal V_{CL} (see FIG. 6) indicating presence or absence of the off-event.

The solid-state imaging element 200 executes predetermined signal processing such as image recognition processing on image data including the detection signal, and outputs the processed data to the recording unit 120 via a signal line 209.

The recording unit 120 records the data from the solid-state imaging element 200. The control unit 130 controls the solid-state imaging element 200 and causes the solid-state imaging element 200 to capture the image data.

[Configuration of a Solid-State Imaging Element]

Next, a configuration of the solid-state imaging element 200 according to the embodiment will be described with reference to FIG. 2 to FIG. 9. FIG. 2 is a view for describing a stacked structure of the solid-state imaging element 200 according to the embodiment of the present disclosure.

The solid-state imaging element 200 according to the embodiment includes a circuit board 202, and a light receiving substrate 201 stacked on the circuit board 202. The light receiving substrate 201 and the circuit board 202 are electrically connected via a connecting portion such as a via, Cu—Cu bonding, or a bump.

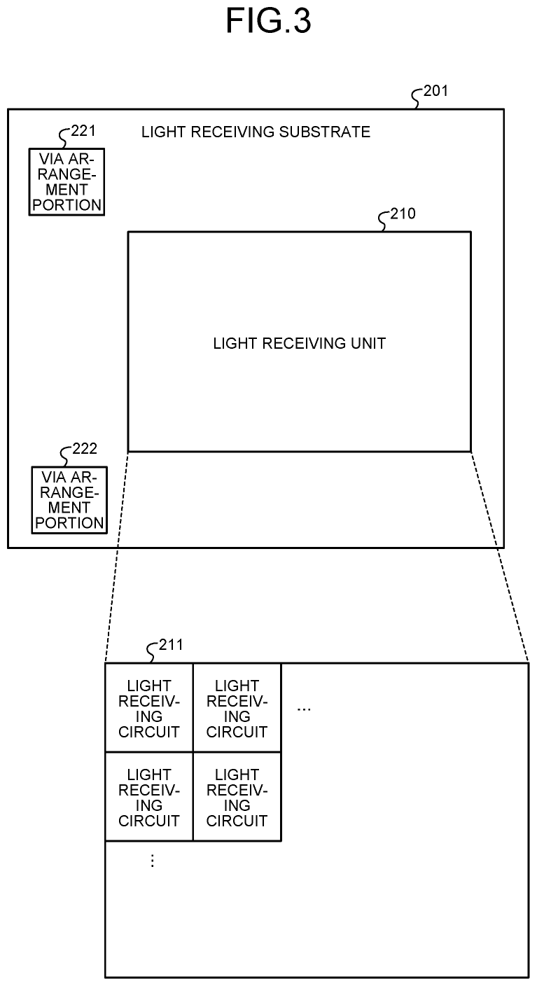

FIG. 3 is a view for describing a plane configuration of the light receiving substrate 201 according to the embodiment of the present disclosure. As illustrated in FIG. 3, the light receiving substrate 201 includes a light receiving unit 210, a via arrangement portion 221, and a via arrangement portion 222.

In the light receiving unit 210, a plurality of light receiving circuits 211 is arrayed in a two-dimensional lattice pattern. Each of the light receiving circuits 211 generates a photocurrent by photoelectric conversion of incident light, performs current/voltage conversion of the photocurrent, and outputs a voltage signal. A pixel address including a row address and a column address is assigned to each of the light receiving circuits 211.

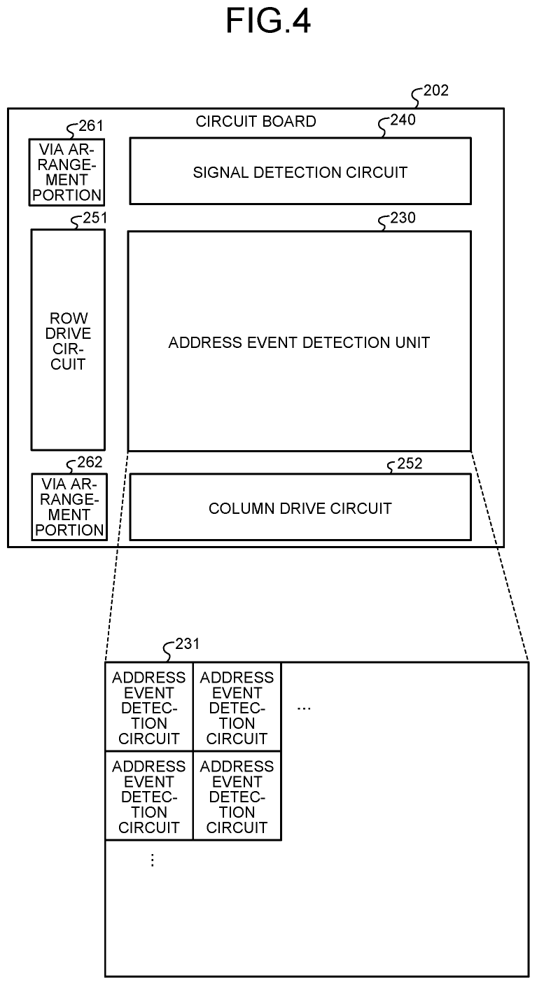

Vias connected to the circuit board 202 (see FIG. 4) are arranged in the via arrangement portion 221 and the via arrangement portion 222.

FIG. 4 is a view for describing a plane configuration of the circuit board 202 according to the embodiment of the present disclosure. As illustrated in FIG. 4, the circuit board 202 includes an address event detection unit 230, a signal processing circuit 240, a row drive circuit 251, a column drive circuit 252, a via arrangement portion 261, and a via arrangement portion 262.

In the address event detection unit 230, a plurality of address event detection circuits 231 is arrayed in the two-dimensional lattice pattern. Each of the address event detection circuits 231 quantizes the voltage signal from the light receiving circuit 211 and outputs the quantized voltage signal as a detection signal.

A pixel address is assigned to each of the address event detection circuits 231, and each of the address event detection circuits 231 is electrically connected to the light receiving circuit 211 having the same address. Furthermore, the light receiving circuit 211 and the address event detection circuit 231 having the same address are arranged at the same position in plan view in the embodiment.

The signal processing circuit 240 executes predetermined signal processing on detection signals from the address event detection unit 230. For example, the signal processing circuit 240 arrays the detection signals as pixel signals in the two-dimensional lattice pattern, and acquires image data having 2-bit information for each pixel. Then, the signal processing circuit 240 executes signal processing such as image recognition processing on the acquired image data.

The row drive circuit 251 selects a row address and causes the address event detection unit 230 to output a detection signal corresponding to the selected row address. The column drive circuit 252 selects a column address and causes the address event detection unit 230 to output a detection signal corresponding to the selected column address. Vias connected to the light receiving substrate 201 (see FIG. 3) are arranged in the via arrangement portion 261 and the via arrangement portion 262.

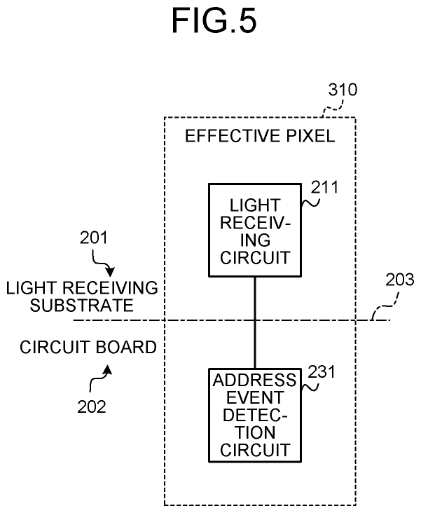

FIG. 5 is a view for describing a configuration of an effective pixel 310 according to the embodiment of the present disclosure. As illustrated in FIG. 5, each of the effective pixels 310 includes a light receiving circuit 211 in the light receiving substrate 201 and an address event detection circuit 231 in the circuit board 202 to which circuits the same pixel address is assigned.

As described above, on the light receiving substrate 201 and the circuit board 202, the plurality of light receiving circuits 211 and the plurality of address event detection circuits 231 are arrayed in the two-dimensional lattice pattern. In addition, the light receiving circuit 211 and the address event detection circuit 231 having the same address are arranged at the same position in plan view.

That is, in the solid-state imaging element 200 according to the embodiment, the effective pixels 310, each of which includes a pair of the light receiving circuit 211 and the address event detection circuit 231, are arrayed in the two-dimensional lattice pattern. Then, the pair of light receiving circuit 211 and the address event detection circuit 231 is electrically connected via a connecting portion such as a via, Cu—Cu bonding, or a bump at a bonding portion 203.

FIG. 6 is a view illustrating a circuit configuration of each of the effective pixels 310 according to the embodiment of the present disclosure. As illustrated in FIG. 6, the effective pixel 310 includes a photodiode 311, a current/voltage conversion circuit 320, a buffer 330, a subtractor 340, a quantizer 350, and a transfer circuit 360. The photodiode 311 is an example of a photoelectric conversion element.

In the embodiment of the present disclosure, the photodiode 311, and N-type transistors 321 and 322 of the current/voltage conversion circuit 320 among the units of the effective pixel 310 are included in the light receiving circuit 211. Furthermore, among the units of the effective pixel 310, the buffer 330, the subtractor 340, the quantizer 350, and the transfer circuit 360 are included in the address event detection circuit 231.

That is, in the embodiment of the present disclosure, the effective pixel 310 includes the photodiode 311, the current/voltage conversion circuit 320, and the address event detection circuit 231.

The photodiode 311 photoelectrically converts incident light and generates a photocurrent. Then, the photodiode 311 supplies the generated photocurrent to the current/voltage conversion circuit 320.

The current/voltage conversion circuit 320 converts the photocurrent from the photodiode 311 into a logarithmic voltage signal. Then, the current/voltage conversion circuit 320 supplies the converted voltage signal to the buffer 330.

The buffer 330 corrects the voltage signal transmitted from the current/voltage conversion circuit 320 and outputs the corrected signal to the subtractor 340. In the effective pixel 310 according to the embodiment, it is possible to improve driving force to drive a subsequent stage by the buffer 330 and to secure isolation of noise associated with switching operation in the subsequent stage.

By subtraction processing, the subtractor 340 calculates a change amount of a correction signal transmitted from the buffer 330. Then, the subtractor 340 supplies the calculated change amount to the quantizer 350 as a differential signal.

The quantizer 350 converts (that is, quantizes) the analog differential signal into a digital detection signal by comparing the differential signal with a predetermined threshold. The quantizer 350 according to the embodiment compares the differential signal with each of an upper limit threshold and a lower limit threshold, and supplies a comparison result to the transfer circuit 360 as a 2-bit detection signal.

The transfer circuit 360 transfers the detection signal to the signal processing circuit 240 according to a column drive signal from the column drive circuit 252.

A specific circuit configuration of each unit will be described in the following. The current/voltage conversion circuit 320 includes the N-type transistor 321, the N-type transistor 322, and a P-type transistor 323. As the N-type transistor 321, the N-type transistor 322, and the P-type transistor 323, for example, metal-oxide-semiconductor (MOS) transistors are used.

A source of the N-type transistor 321 is connected to a cathode of the photodiode 311, and a drain is connected to a terminal of a first voltage VDD1. An anode of the photodiode 311 is connected to a terminal of ground potential. The P-type transistor 323 and the N-type transistor 322 are connected in series in this order between the terminal of the first voltage VDD1 and the terminal of the ground potential.

As described above, in the present disclosure, the photodiode 311 and each of the transistors included in the current/voltage conversion circuit 320 are driven by the first voltage VDD1. The first voltage VDD1 is, for example, 2.2 (V) to 2.8 (V).

A connection point between the P-type transistor 323 and the N-type transistor 322 is connected to a gate of the N-type transistor 321 and an input terminal of the buffer 330. A connection point between the N-type transistor 321 and the photodiode 311 is connected to a gate of the N-type transistor 322. A predetermined bias voltage V_{blog} is applied to a gate of the P-type transistor 323.

Then, the N-type transistor 321 converts the photocurrent generated by the photodiode 311 into a voltage between the gate and the source, and the N-type transistor 322 amplifies the voltage between the gate having potential corresponding to the photocurrent and the source having the ground potential and outputs the amplified voltage from a drain.

Furthermore, the P-type transistor 323 supplies a constant current based on the bias voltage V_{blog} to the N-type transistor 322. With such a configuration, the current/voltage conversion circuit 320 converts the photocurrent from the photodiode 311 into the voltage signal.

Note that in the solid-state imaging element 200 according to the embodiment, the photodiode 311, the N-type transistor 321, and the N-type transistor 322 are arranged on the light receiving substrate 201, and circuits from the P-type transistor 323 are arranged on the circuit board 202.

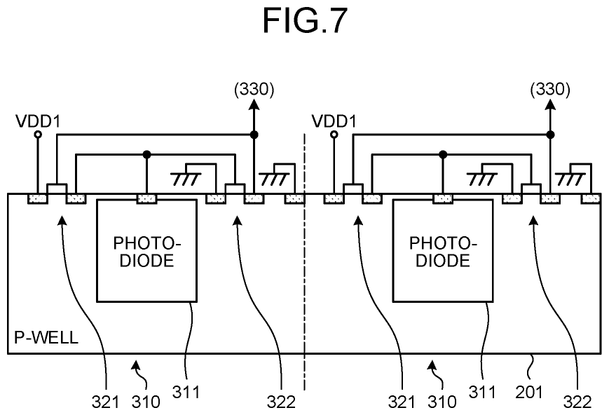

FIG. 7 is a view for describing configurations of the effective pixels 310 according to the embodiment of the present disclosure. As illustrated in FIG. 7, the photodiode 311 is embedded in a P-well region of the light receiving substrate 201, and a back gate of the N-type transistor 321 and a back gate of the N-type transistor 322 are formed.

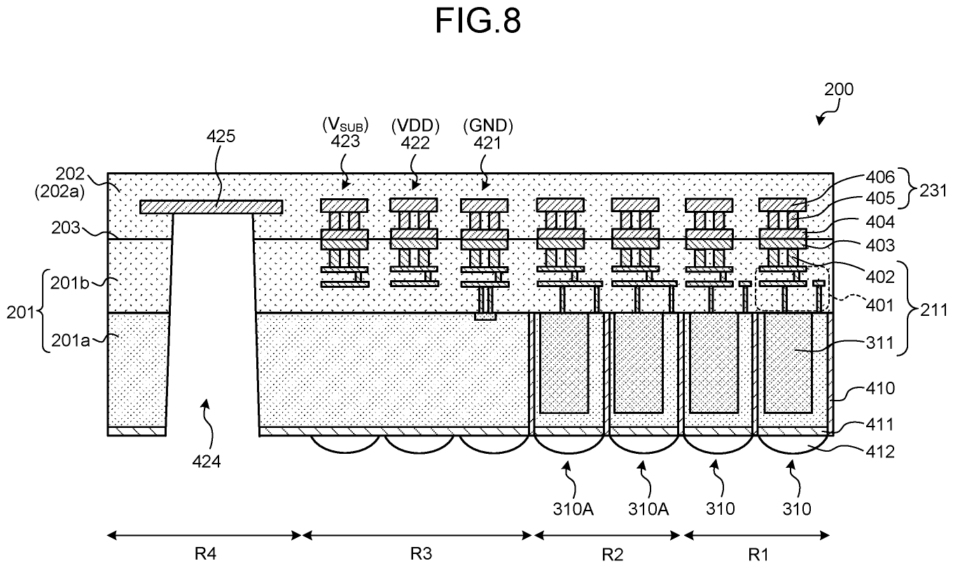

The first voltage VDD1 is supplied to the drain of the N-type transistor 321, and potential of the P-well region (that is, the anode of the photodiode 311) and the potential of the source of the N-type transistor 322 are the ground potential. Furthermore, the P-well regions of the adjacent effective pixels 310 are isolated by a pixel isolation portion 410 (see FIG. 8) formed in a portion of a dash-dotted line.

The description returns to FIG. 6. The buffer 330 includes a P-type transistor 331 and a P-type transistor 332. For the P-type transistor 331 and the P-type transistor 332, for example, MOS transistors are used.

The P-type transistor 331 and the P-type transistor 332 are connected in series in this order between the terminal of the first voltage VDD1 and the terminal of the ground potential. Furthermore, a predetermined bias voltage V_{bsf} is applied to a gate of the P-type transistor 331. A gate of the P-type transistor 332 is connected to an output terminal of the current/voltage conversion circuit 320.

With such a configuration, the buffer 330 outputs a corrected voltage signal from a connection point between the P-type transistor 331 and the P-type transistor 332 to the subtractor 340. Furthermore, in the present disclosure, each of the transistors included in the buffer 330 is driven by the first voltage VDD1.

The subtractor 340 includes a capacitor 341, a P-type transistor 342, a capacitor 343, a P-type transistor 344, and an N-type transistor 345. For example, MOS transistors are used as the P-type transistor 342, the P-type transistor 344, and the N-type transistor 345.

The P-type transistor 344 and the N-type transistor 345 are connected in series in this order between a terminal of a second voltage VDD2 and a terminal of reference potential. Furthermore, a predetermined bias voltage V_{ba} is applied to a gate of the N-type transistor 345.

The P-type transistor 344 and the N-type transistor 345 function as inverters that invert and output an input signal in a case where a gate of the P-type transistor 344 is an input terminal and a connection point between the P-type transistor 344 and the N-type transistor 345 is an output terminal.

One end of the capacitor 341 is connected to an output terminal of the buffer 330, and the other end is connected to the input terminal of the inverter (that is, the gate of the P-type transistor 344). One end of the capacitor 343 is connected to the input terminal of the inverter, and the other end is connected to the output terminal of the inverter (that is, the connection point between the P-type transistor 344 and the N-type transistor 345).

The P-type transistor 342 opens and closes a path connecting both ends of the capacitor 343 according to a row drive signal output from the row drive circuit 251.

When the P-type transistor 342 is turned on, a voltage signal Vᵢₙᵢₜ is input to a side of the buffer 330 of the capacitor 341, and an opposite side becomes a virtual ground terminal. It is assumed that potential of the virtual ground terminal is zero for convenience.

At this time, a charge Qᵢₙᵢₜ accumulated in the capacitor 341 is expressed by the following expression (1) when capacitance of the capacitor 341 is C1. On the other hand, since both ends of the capacitor 343 are short-circuited, the accumulated charge becomes zero.

Qᵢₙᵢₜ=C1×Vᵢₙᵢₜ (1)

Next, considering a case where the P-type transistor 342 is turned off and a voltage on a side of the buffer 330 of the capacitor 341 changes to V_{after}, a charge Q_{after} accumulated in the capacitor 341 is expressed by the following expression (2).

Q_{after}=C1×V_{after} (2)

On the other hand, a charge Q2 accumulated in the capacitor 343 is expressed by the following expression (3), when capacitance of the capacitor 343 is C2 and an output voltage is Vₒᵤₜ.

Q2=−C2×Vₒᵤₜ (3)

At this time, since the total charge amounts of the capacitor 341 and the capacitor 343 do not change, the following expression (4) is established.

Qᵢₙᵢₜ=Q_{after}+Q2 (4)

Then, when the expressions (1) to (3) are substituted into the above expression (4) and the expression is deformed, the following expression (5) is acquired.

Vₒᵤₜ=−(C1/C2)×(V_{after}−Vᵢₙᵢₜ) (5)

The above expression (5) expresses a subtraction operation of the voltage signal, and gain of a subtraction result is C1/C2. Normally, it is desired to maximize the gain, and thus it is preferable to design the capacitance C1 to be large and the capacitance C2 to be small. On the other hand, when the capacitance C2 is too small, kTC noise increases, and a noise characteristic may be deteriorated. Thus, the capacitance reduction of the capacitance C2 is limited to a range in which the noise can be permitted.

Furthermore, since the subtractor 340 is mounted for each of the effective pixels 310, the capacitance C1 and the capacitance C2 have area restrictions. In view of the above, for example, the capacitance C1 is set to a value of 20 to 200 femtofarads (fF), and the capacitance C2 is set to a value of 1 to 20 femtofarads (fF).

In the present disclosure, each of the transistors included in the subtractor 340 is driven by the second voltage VDD2. Such a second voltage VDD2 is a voltage lower than the first voltage VDD1 and is, for example, 0.85 (V). Note that the first voltage VDD1 and the second voltage VDD2 are also collectively referred to as a “power supply voltage VDD” in the following description.

The quantizer 350 includes a P-type transistor 351, an N-type transistor 352, a P-type transistor 353, and an N-type transistor 354. For example, MOS transistors are used as the P-type transistor 351, the N-type transistor 352, the P-type transistor 353, and the N-type transistor 354.

The P-type transistor 351 and the N-type transistor 352 are connected in series in this order between the terminal of the second voltage VDD2 and the terminal of the ground potential. The P-type transistor 353 and the N-type transistor 354 are connected in series in this order between the terminal of the second voltage VDD2 and the terminal of the reference potential.

Furthermore, a gate of the P-type transistor 351 and a gate of the P-type transistor 353 are connected to an output terminal of the subtractor 340. A bias voltage V_{bon} indicating the upper limit threshold is applied to a gate of the N-type transistor 352, and a bias voltage V_{boff} indicating the lower limit threshold is applied to a gate of the N-type transistor 354.

A connection point of the P-type transistor 351 and the N-type transistor 352 is connected to the transfer circuit 360. In the quantizer 350, a voltage at the connection point is output to the transfer circuit 360 as the on-event detection signal V_{CH}.

A connection point of the P-type transistor 353 and the N-type transistor 354 is connected to the transfer circuit 360. In the quantizer 350, a voltage at the connection point is output as the off-event detection signal V_{CL}.

With such a configuration, the quantizer 350 outputs the high-level on-event detection signal V_{CH} in a case where the differential signal exceeds the upper limit threshold, and outputs the low-level off-event detection signal V_{CL}, in a case where the differential signal falls below the lower limit threshold. That is, the solid-state imaging element 200 according to the embodiment can simultaneously detect presence or absence of both an on-event and an off-event.

In the present disclosure, each of the transistors included in the quantizer 350 is driven by the second voltage VDD2.

FIG. 8 is a view illustrating a cross-sectional configuration of the solid-state imaging element 200 according to the embodiment of the present disclosure, a cross-sectional structure of a peripheral portion of the solid-state imaging element 200 being illustrated. As illustrated in FIG. 8, the solid-state imaging element 200 includes an effective pixel region R1, a dummy pixel region R2, a power supply region R3, and a pad region R4.

The effective pixel region R1 is a region in which the stacked light receiving unit 210 and the address event detection unit 230 are provided. In the effective pixel region R1, the plurality of effective pixels 310 is arrayed in the two-dimensional lattice pattern.

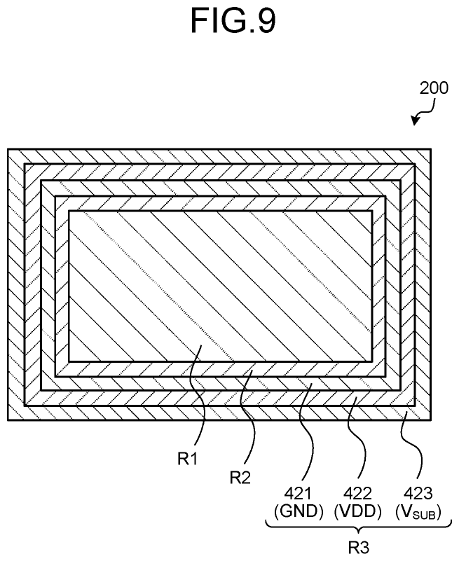

As illustrated in FIG. 9, the dummy pixel region R2 is a region provided in such a manner as to surround four sides of the effective pixel region R1. FIG. 9 is a view illustrating a plane configuration of the solid-state imaging element 200 according to the embodiment of the present disclosure.

Furthermore, as illustrated in FIG. 8, a plurality of dummy pixels 310A is arrayed side by side in the dummy pixel region R2. Although having the same basic configuration as the effective pixels 310, the dummy pixels 310A output no signal to the outside.

In the solid-state imaging element 200 according to the embodiment, the dummy pixel region R2 is formed in such a manner as to surround the four sides of the effective pixel region R1, whereby regularity of a process from a center to an edge portion of the effective pixel region R1 can be secured. Thus, according to the embodiment, a manufacturing yield of the solid-state imaging element 200 can be improved.

As illustrated in FIG. 9, the power supply region R3 is a region provided in such a manner as to surround four sides of the dummy pixel region R2. The power supply region R3 includes a ground wiring line 421 to which the ground potential is applied from the outside, a power supply wiring line 422 to which the power supply voltage VDD is applied from the outside, and a power supply wiring line 423 to which a substrate voltage VSUB is applied from the outside. The ground wiring line 421 and the power supply wiring lines 422 and 423 are formed in a ring shape around the dummy pixel region R2, for example.

The ground wiring line 421 supplies the ground potential to the plurality of effective pixels 310 and the like. The power supply wiring line 422 supplies the power supply voltage VDD to the plurality of effective pixels 310 and the like. The power supply wiring line 423 supplies the substrate voltage V_{SUB} having the same potential as the power supply voltage VDD to a portion other than the effective pixel region R1 and the dummy pixel region R2 of the solid-state imaging element 200.

In the solid-state imaging element 200 according to the embodiment, the power supply wiring line 423 is provided separately from the power supply wiring line 422. Thus, even in a case where the power supply voltage VDD fluctuates, for example, when the effective pixels 310 operate, the stable substrate voltage VSUB can be supplied to the peripheral portion of the solid-state imaging element 200. Thus, according to the embodiment, the solid-state imaging element 200 can be operated stably.

The description returns to FIG. 8. The pad region R4 is a region provided around the power supply region R3, and includes a contact hole 424 and a bonding pad 425. The contact hole 424 is formed in a thickness direction of the light receiving substrate 201 and the circuit board 202 from a surface on a light incident side of the light receiving substrate 201 to the middle of the circuit board 202.

The bonding pad 425 is provided at a bottom of the contact hole 424. In the embodiment, a bonding wire or the like is bonded to the bonding pad 425 via the contact hole 424, whereby the recording unit 120 (see FIG. 1) or the control unit 130 (see FIG. 1) is electrically connected to each unit of the solid-state imaging element 200.

The configuration of the effective pixels 310 arranged in the effective pixel region R1 will be further described with reference to FIG. 8. The solid-state imaging element 200 is configured by stacking of the light receiving substrate 201 and the circuit board 202. The bonding portion 203 is provided at an interface between the light receiving substrate 201 and the circuit board 202.

The light receiving substrate 201 includes a semiconductor layer 201a and an insulating layer 201b. The semiconductor layer 201a is made of a semiconductor material such as silicon. In the semiconductor layer 201a, the photodiode 311 (see FIG. 7), the N-type transistor 321 (see FIG. 7), the N-type transistor 322 (see FIG. 7), and the like are formed for each of the effective pixels 310 or the dummy pixels 310A.

Furthermore, in the semiconductor layer 201a, the pixel isolation portion 410 is formed in such a manner as to isolate the adjacent effective pixels 310 and dummy pixels 310A from each other. The pixel isolation portion 410 electrically and optically isolates the adjacent effective pixels 310 and dummy pixels 310A from each other.

For example, the pixel isolation portion 410 is formed in such a manner as to individually surround the effective pixels 310 and the dummy pixels 310A and to penetrate the semiconductor layer 201a.

A planarization film 411 is formed on the surface on the light incident side of the semiconductor layer 201a, and an on-chip lens 412 is formed on a surface on the light incident side of the planarization film 411. The planarization film 411 planarizes a surface on which the on-chip lens 412 is mounted.

For example, the on-chip lens 412 is individually provided in the effective pixels 310 or the dummy pixels 310A, collects incident light, and guides the incident light to the effective pixels 310 or the dummy pixels 310A.

The insulating layer 201b is made of an insulating material such as silicon oxide (SiOₓ), silicon nitride (SiN), or silicon oxynitride (SiON), and is provided on a surface, which is on an opposite side of the light incident side, of the semiconductor layer 201a.

In addition, a wiring portion 401 including a wiring layer, a via, and the like is formed in the insulating layer 201b. The wiring portion 401 is electrically connected to the photodiode 311, the N-type transistor 321, and the N-type transistor 322 provided in the semiconductor layer 201a by a wiring configuration illustrated in FIG. 6.

The wiring portion 401 is electrically connected to a pad 403 via a via 402. The pad 403 is provided in a manner of being exposed to a surface, which is on an opposite side of the surface on the light incident side, of the light receiving substrate 201 (that is, the interface with the circuit board 202), and is made of copper or a copper alloy.

The circuit board 202 has an insulating layer 202a on a side of the interface with the light receiving substrate 201. The insulating layer 202a is made of an insulating material such as silicon oxide, silicon nitride, or silicon oxynitride.

Furthermore, the insulating layer 202a includes a pad 404. The pad 404 is provided in a manner of being exposed to a surface on the light incident side of the circuit board 202 (that is, the interface with the light receiving substrate 201), and is made of copper or a copper alloy.

The pad 404 is electrically connected to a wiring portion 406 via a via 405. The wiring portion 406 includes a wiring layer, a via, and the like, and is electrically connected to the gate of the P-type transistor 332 (see FIG. 6) and a source of the P-type transistor 323 (see FIG. 6). In the embodiment, the pad 403 and the pad 404 are directly bonded by Cu—Cu bonding.

[Configuration of a Circuit Board]

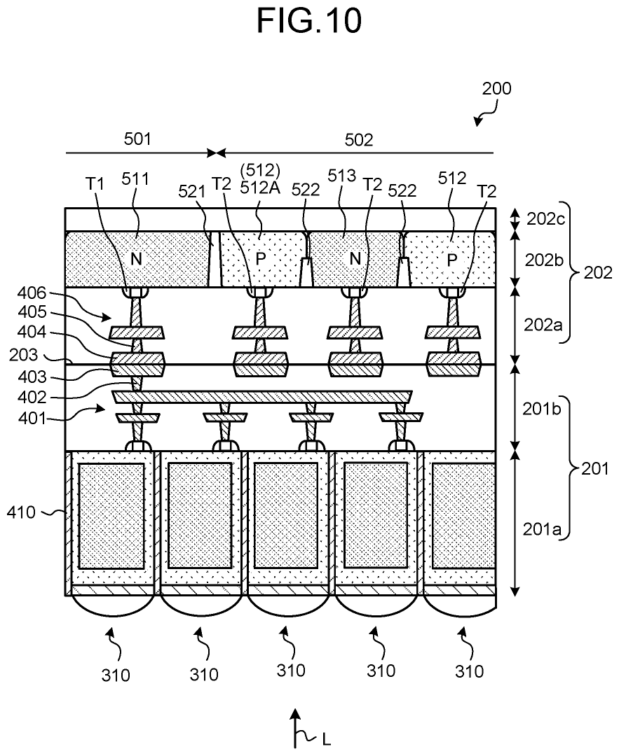

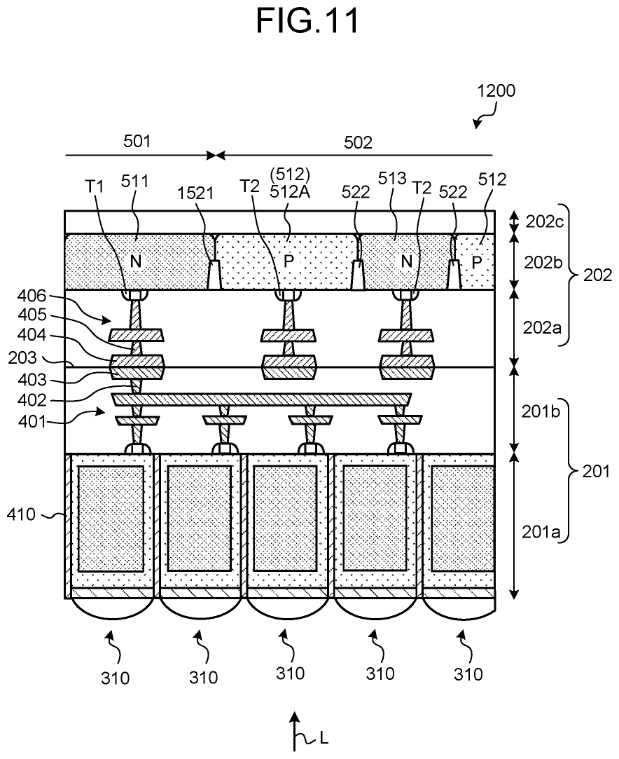

Next, a detailed configuration of the circuit board 202 according to the embodiment will be described with reference to FIG. 10 and FIG. 11. FIG. 10 is a view illustrating a cross-sectional configuration of the solid-state imaging element 200 according to the embodiment of the present disclosure.

As illustrated in FIG. 10, the solid-state imaging element 200 is configured by stacking of the light receiving substrate 201 and the circuit board 202. The bonding portion 203 is provided at the interface between the light receiving substrate 201 and the circuit board 202.

Furthermore, the light receiving substrate 201 includes the semiconductor layer 201a and the insulating layer 201b. The semiconductor layer 201a is made of a semiconductor material such as silicon. In the semiconductor layer 201a, the photodiode 311 (see FIG. 7), the N-type transistor 321 (see FIG. 7), the N-type transistor 322 (see FIG. 7), and the like are formed for each of the effective pixels 310.

The insulating layer 201b is made of an insulating material such as silicon oxide, silicon nitride, or silicon oxynitride, and is provided on a surface, which is on an opposite side of an incident side of light L, of the semiconductor layer 201a. The wiring portion 401, the via 402, the pad 403, and the like are formed inside the insulating layer 201b.

The circuit board 202 includes the insulating layer 202a, a semiconductor layer 202b, and an insulating layer 202c stacked in this order from the light incident side.

The insulating layer 202a is arranged on a side of the interface with the light receiving substrate 201 in the circuit board 202. The insulating layer 202a is made of an insulating material such as silicon oxide, silicon nitride, or silicon oxynitride. In addition, the pad 404, the via 405, the wiring portion 406, and the like are formed inside the insulating layer 202a.

The semiconductor layer 202b is made of a semiconductor material such as silicon. An N-well region 511, a P-well region 512, an N-well region 513, and the like are provided in the semiconductor layer 202b.

The N-well region 511 is an example of a first well region, the P-well region 512 is an example of a second well region, and the N-well region 513 is an example of a third well region.

In the N-well region 511, various transistors provided in the circuit board 202 and driven by the first voltage VDD1 (see FIG. 6) are arranged. In the N-well region 511, for example, the P-type transistor 323 (see FIG. 6), the P-type transistor 331 (see FIG. 6), the P-type transistor 332 (see FIG. 6), and the like are arranged.

Then, in the present disclosure, in the semiconductor layer 202b, a region in which the various transistors driven by the first voltage VDD1 are arranged (such as the N-well region 511) is defined as a first element region 501. In addition, the various transistors arranged in the first element region 501 are collectively referred to as a first transistor T1 in the present disclosure.

In the P-well region 512, various N-type transistors provided in the circuit board 202 and driven by the second voltage VDD2 (see FIG. 6) are arranged. In the P-well region 512, for example, the N-type transistor 345 (see FIG. 6), the N-type transistor 352 (see FIG. 6), the N-type transistor 354 (see FIG. 6), and the like are arranged.

In the N-well region 513, various P-type transistors provided in the circuit board 202 and driven by the second voltage VDD2 are arranged. In the N-well region 513, for example, the P-type transistor 342 (see FIG. 6), the P-type transistor 344 (see FIG. 6), the P-type transistor 351 (see FIG. 6), the P-type transistor 353 (see FIG. 6), and the like are arranged.

In the present disclosure, in semiconductor layer 202b, a region in which the various transistors driven by the second voltage VDD2 are arranged (such as the P-well region 512 and N-well region 513) is defined as a second element region 502. In addition, the various transistors arranged in the second element region 502 are collectively referred to as a second transistor T2 in the present disclosure.

Here, in the embodiment, a full trench isolation (FTI) structure 521 is arranged between the first element region 501 and the second element region 502 adjacent to each other.

Note that in the present disclosure, the “FTI structure” means a structure in which a trench is formed from a surface on the light incident side to a surface on the opposite side of the light incident side of the semiconductor layer 202b and an insulating material (such as silicon oxide or the like) is embedded in the trench.

In the embodiment, the FTI structure 521 is arranged in such a manner as to surround a periphery of the first element region 501 and is arranged in such a manner as to extend substantially perpendicularly with respect to the surface of the circuit board 202 (that is, to extend in an incident direction of the light L).

Here, effects acquired by the arrangement of the FTI structure 521 between the first element region 501 and the second element region 502 will be described with reference to FIG. 11. FIG. 11 is a view illustrating a cross-sectional configuration of a solid-state imaging element 1200 in a reference example of the present disclosure.

In the reference example illustrated in FIG. 11, a shallow trench isolation (STI) structure 1521 is arranged between a first element region 501, to which a first voltage VDD1 is applied, and a second element region 502 to which a second voltage VDD2 is applied.

In the present disclosure, the “STI structure” is a structure in which a trench is formed in such a manner as to extend from the surface on the light incident side of the semiconductor layer 202b and not to reach the surface on the opposite side of the light incident side and an insulating material (such as silicon oxide or the like) is embedded in the trench.

In this reference example, an N-well region 511 of the first element region 501 and an N-well region 513 of the second element region 502 cannot be electrically isolated sufficiently only by the STI structure 1521 arranged between the first element region 501 and the second element region 502.

Thus, in the reference example, as illustrated in FIG. 11, a method of securing electrical isolation between the N-well region 511 and the N-well region 513 by increasing a width of a P-well region 512A, which is directly adjacent to the N well region 511, in a P-well region 512 is adopted.

That is, in the reference example, since an area of the P-well region 512A needs to be increased, it is difficult to reduce an area of an address event detection circuit 231 (see FIG. 5) including the P-well region 512A.

Then, as described above, since the address event detection circuits 231 are individually and respectively provided in effective pixels 310, it is difficult to reduce areas of the effective pixels 310 in the reference example in which it is difficult to reduce the areas of the address event detection circuits 231.

On the other hand, in the embodiment illustrated in FIG. 10, the FTI structure 521 is arranged between the first element region 501 and the second element region 502. Then, in the embodiment, the N-well region 511 of the first element region 501 and the N-well region 513 of the second element region 502 can be electrically isolated approximately only by the FTI structure 521.

Thus, as illustrated in FIG. 10, a width of a P-well region 512A, which is directly adjacent to the N-well region 511, in the P-well region 512 can be reduced in the embodiment.

That is, in the embodiment, since an area of the P-well region 512A can be reduced, an area of the address event detection circuit 231 (see FIG. 5) including the P-well region 512A can be reduced.

Thus, according to the embodiment, areas of the effective pixels 310 can be reduced.

In addition, in the embodiment, in the second element region 502, an STI structure 522 is preferably arranged between the P-well region 512 and the N-well region 513 adjacent to each other. This makes it possible to improve an electrical isolation characteristic inside the second element region 502.

Thus, according to the embodiment, it is possible to control deterioration in signal quality of the address event detection circuit 231 due to noise caused by disturbance or the like.

The description of other parts illustrated in FIG. 10 will be continued. The insulating layer 202c is arranged in such a manner as to be in contact with a surface on the opposite side of the light incident side of the semiconductor layer 202b. The insulating layer 202c is made of an insulating material such as silicon oxide, silicon nitride, or silicon oxynitride.

In the embodiment, the insulating layer 202c is arranged in such a manner as to cover the first element region 501 and the second element region 502, and an end portion on the opposite side of the light incident side of the FTI structure 521 is arranged in such a manner as to be in contact with the insulating layer 202c.

As a result, the N-well region 511 of the first element region 501 and the N-well region 513 of the second element region 502 can be electrically isolated well.

Thus, according to the embodiment, since the width of the P-well region 512A can be further reduced, the area of the effective pixel 310 can be further reduced.

In the embodiment, for example, it is possible to form the circuit board 202 on which the insulating layer 202c is arranged by forming the circuit board 202 by using a silicon on insulator (SOI) substrate.

Furthermore, in the embodiment, the wiring lines of the light receiving substrate 201 and the circuit board 202 are preferably directly bonded to each other. That is, in the embodiment, the wiring portion 401 of the light receiving substrate 201 and the wiring portion 406 of the circuit board 202 are preferably electrically connected by direct bonding of the pad 403 and the pad 404 by Cu—Cu bonding.

As a result, since the number of wiring lines that need to be connected at the via arrangement portions 221, 222, 261, and 262 (See FIGS. 3 and 4) can be reduced, areas of the via arrangement portions 221, 222, 261, and 262 can be reduced.

Thus, according to the embodiment, since additional effective pixels 310 can be arranged in regions where the via arrangement portions 221, 222, 261, and 262 are reduced, the resolution of the solid-state imaging element 200 can be improved.

### First and Second Modification Examples

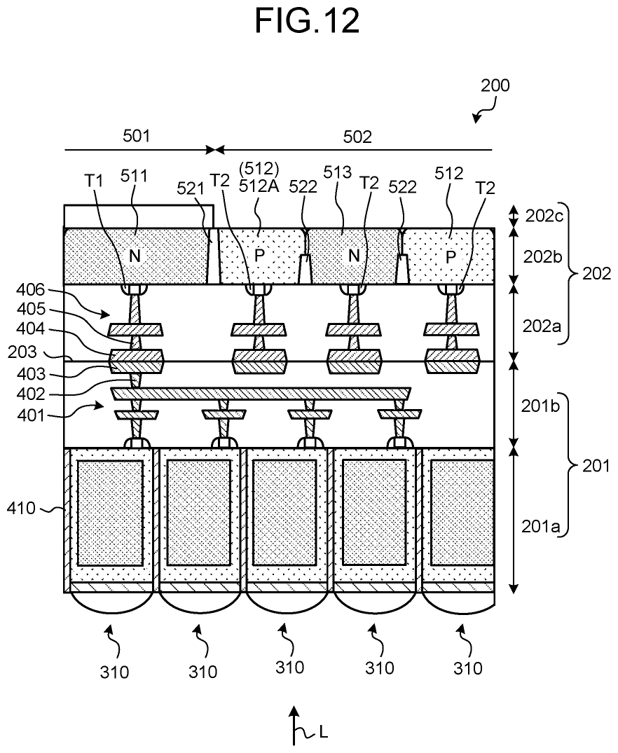

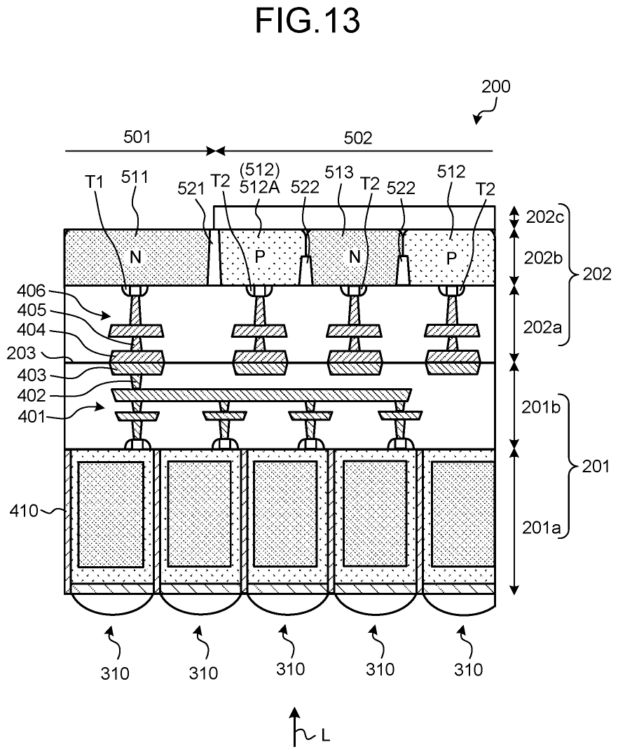

Next, various modification examples of the embodiment will be described with reference to FIG. 12 to FIG. 18. FIG. 12 is a view illustrating a cross-sectional configuration of a solid-state imaging element 200 according to the first modification example of the embodiment of the present disclosure, and FIG. 13 is a view illustrating a cross-sectional configuration of a solid-state imaging element 200 according to the second modification example of the embodiment of the present disclosure.

As illustrated in FIG. 12, an insulating layer 202c may be arranged in such a manner as to cover only a first element region 501. In this case, a part of an end portion on an opposite side of a light incident side of an FTI structure 521 is preferably in contact with the insulating layer 202c.

As a result, an N-well region 511 of the first element region 501 and an N-well region 513 of a second element region 502 can be also electrically isolated well.

Thus, according to the first modification example, since a width of a P-well region 512A can be further reduced, an area of an effective pixel 310 can be further reduced.

Furthermore, an insulating layer 202c is not limited to a case of being arranged to cover only a first element region 501, and may be arranged to cover only a second element region 502 as illustrated in FIG. 13. Also in this case, a part of an end portion on an opposite side of a light incident side of an FTI structure 521 is preferably in contact with the insulating layer 202c.

As a result, an N-well region 511 of the first element region 501 and an N-well region 513 of the second element region 502 can be also electrically isolated well.

Thus, according to the second modification example, since a width of a P-well region 512A can be further reduced, an area of an effective pixel 310 can be further reduced.

Note that an example in which the insulating layer 202c is arranged in such a manner as to cover only the first element region 501 is illustrated in the example of FIG. 12. However, the insulating layer 202c may cover the entire first element region 501 and a part of the second element region 502.

Furthermore, an example in which the insulating layer 202c is arranged in such a manner as to cover only the second element region 502 is illustrated in the example of FIG. 13. However, the insulating layer 202c may cover the entire second element region 502 and a part of the first element region 501.

### Third Modification Example

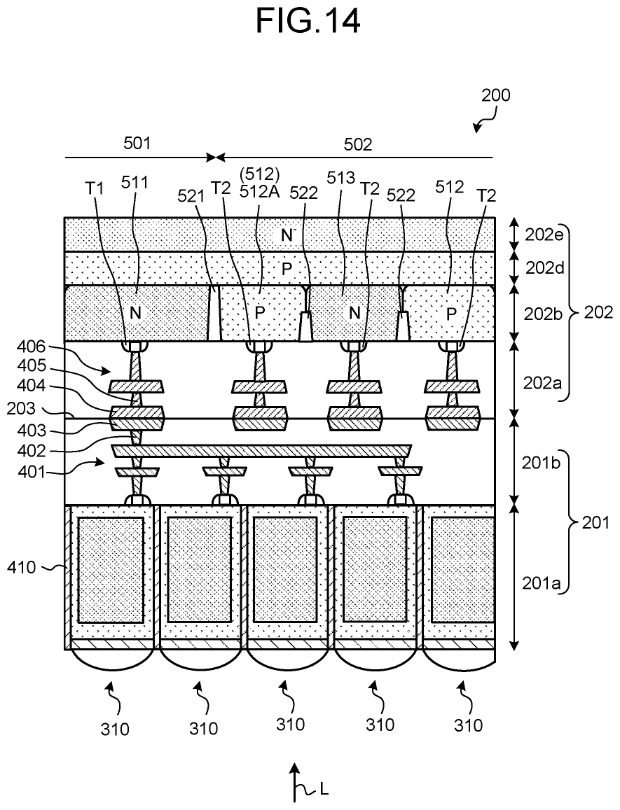

FIG. 14 is a view illustrating a cross-sectional configuration of a solid imaging-state imaging element 200 according to the third modification example of the embodiment of the present disclosure. In the third modification example, a part of a configuration of a circuit board 202 is different from that of the embodiment.

Specifically, in the third modification example, the circuit board 202 includes an insulating layer 202a, a semiconductor layer 202b, a well layer 202d, and a semiconductor layer 202e stacked in this order from a light incident side.

The well layer 202d is a well layer that is made of a semiconductor material such as silicon and has a conductivity type (P type in the drawing) different from that of an N-well region 511. The semiconductor layer 202e is a semiconductor layer that is made of a semiconductor material such as silicon and has a conductivity type (N type in the drawing) different from that of the well layer 202d.

In the third modification example, the well layer 202d having the conductivity type different from that of the N-well region 511 is arranged in such a manner as to cover a first element region 501 and a second element region 502, and an end portion on an opposite side of a light incident side of an FTI structure 521 is arranged in such a manner as to be in contact with the well layer 202d.

As a result, the N-well region 511 of the first element region 501 and the N-well region 513 of the second element region 502 can be electrically isolated well.

Thus, according to the third modification example, since a width of a P-well region 512A can be further reduced, an area of an effective pixel 310 can be further reduced.

Furthermore, in the third modification example, since an isolation structure between the first element region 501 and the second element region 502 can be formed by utilization of the well layer 202d instead of the insulating layer 202c, the circuit board 202 can be manufactured without utilization of a relatively expensive SOI substrate.

Thus, according to the third modification example, a manufacturing cost of the solid-state imaging element 200 can be reduced.

### Fourth and Fifth Modification Examples

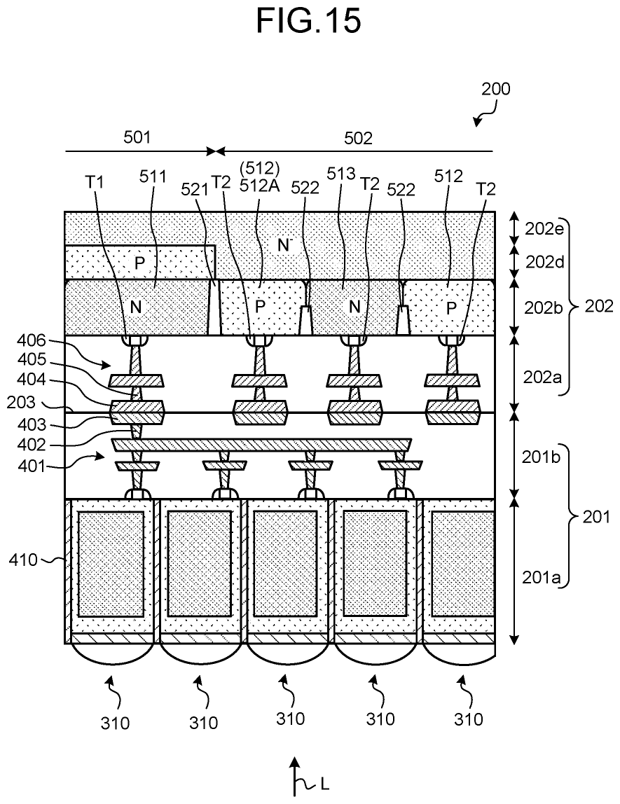

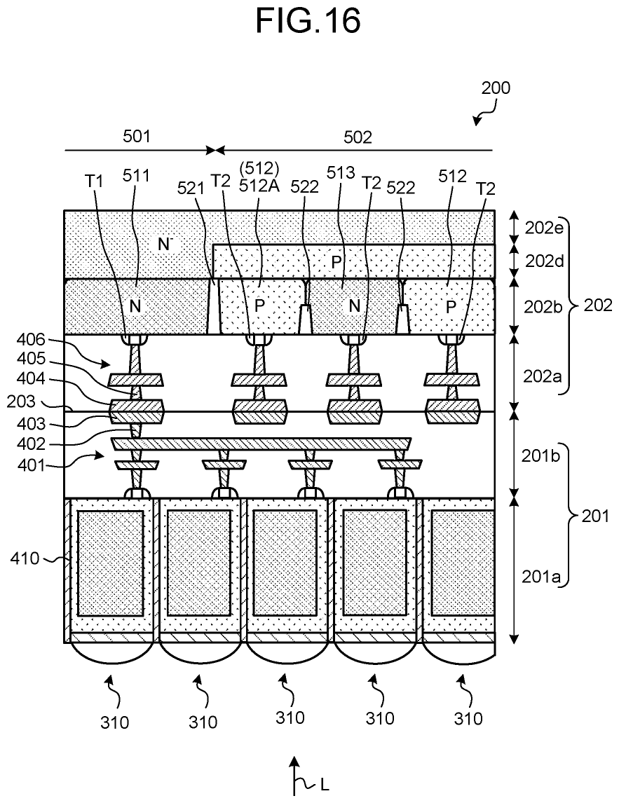

FIG. 15 is a view illustrating a cross-sectional configuration of a solid-state imaging element 200 according to the fourth modification example of the embodiment of the present disclosure, and FIG. 16 is a view illustrating a cross-sectional configuration of a solid-state imaging element 200 according to the fifth modification example of the embodiment of the present disclosure.

As illustrated in FIG. 15, a well layer 202d may be arranged in such a manner as to cover only a first element region 501. In this case, a part of an end portion on an opposite side of a light incident side of an FTI structure 521 is preferably in contact with the well layer 202d.

As a result, an N-well region 511 of the first element region 501 and an N-well region 513 of a second element region 502 can be also electrically isolated well.

Thus, according to the fourth modification example, since a width of a P-well region 512A can be further reduced, an area of an effective pixel 310 can be further reduced.

Furthermore, a well layer 202d is not limited to a case of being arranged to cover only a first element region 501, and may be arranged to cover only a second element region 502 as illustrated in FIG. 16. Also in this case, a part of an end portion on an opposite side of a light incident side of an FTI structure 521 is preferably in contact with the well layer 202d.

As a result, an N-well region 511 of the first element region 501 and an N-well region 513 of a second element region 502 can be also electrically isolated well.

Thus, according to the fifth modification example, since a width of a P-well region 512A can be further reduced, an area of an effective pixel 310 can be further reduced.

Although the well layer 202d is arranged in such a manner as to cover only the first element region 501 in the example of FIG. 15, the well layer 202d may cover the entire first element region 501 and a part of the second element region 502.

Furthermore, although the well layer 202d is arranged in such a manner as to cover only the second element region 502 in the example of FIG. 16, the well layer 202d may cover the entire second element region 502 and a part of the first element region 501.

### Sixth Modification Example

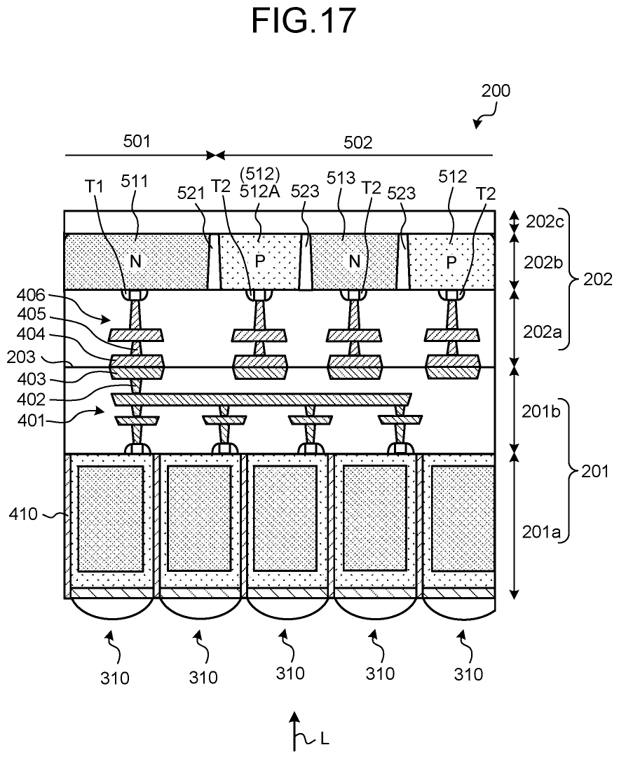

FIG. 17 is a view illustrating a cross-sectional configuration of a solid-state imaging element 200 according to the sixth modification example of the embodiment of the present disclosure. In the sixth modification example, an internal configuration of a second element region 502 is different from that of the embodiment.

Specifically, in the sixth modification example, in the second element region 502, instead of an STI structure 522, an FTI structure 523 is arranged between a P-well region 512 and an N-well region 513 adjacent to each other. The FTI structure 523 is an example of another FTI structure.

This makes it possible to further improve an electrical isolation characteristic inside the second element region 502. Thus, according to the sixth modification example, it is possible to further control deterioration in signal quality of an address event detection circuit 231 (see FIG. 5) due to noise caused by disturbance or the like.

Furthermore, in the sixth modification example, since an FTI structure 521 and the FTI structure 523 can be manufactured in the same process, a manufacturing process of the circuit board 202 can be simplified. Thus, according to the sixth modification example, a manufacturing cost of the solid-state imaging element 200 can be reduced.

Note that although an example in which the P-well regions 512 and the N-well regions 513 are all separated by the FTI structures 523 is illustrated in the example of FIG. 17, the present disclosure is not limited to such an example. For example, in a second element region 502, FTI structures 523 and STI structures 522 may be mixed between P-well regions 512 and N-well regions 513 adjacent to each other.

### Seventh Modification Example

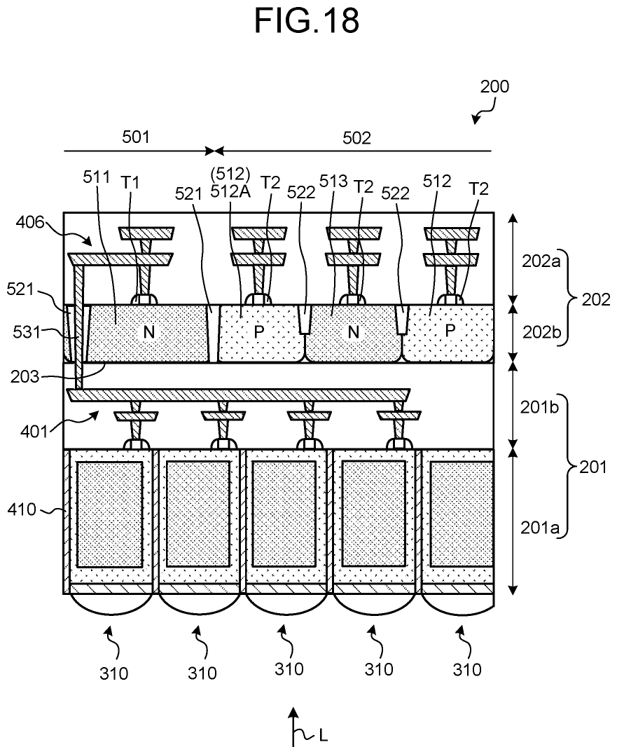

FIG. 18 is a view illustrating a cross-sectional configuration of a solid-state imaging element 200 according to an eighth modification example of the embodiment of the present disclosure. In the seventh modification example, a direction of a circuit board 202 at the time of bonding to a light receiving substrate 201 is different from that of the embodiment.

Specifically, as illustrated in FIG. 18, a semiconductor layer 202b of the circuit board 202 is arranged on a side of the circuit board 202, and an insulating layer 202a is arranged on a side farther from the circuit board 202 than the semiconductor layer 202b. Then, in the seventh modification example, a bonding portion 203 is provided on a side of the semiconductor layer 202b of the circuit board 202.

Even with such a configuration, a width of a P-well region 512A can be reduced by arrangement of an FTI structure 521 between a first element region 501 and a second element region 502. Thus, according to the seventh modification example, an area of an effective pixel 310 can be reduced.

In addition, in the seventh modification example, a wiring portion 401 of the light receiving substrate 201 and a wiring portion 406 of the circuit board 202 are electrically connected by a via 531. Thus, since a process of directly bonding a pad 403 and a pad 404 can be omitted, a process of bonding the light receiving substrate 201 and the circuit board 202 can be simplified.

Furthermore, in the seventh modification example, the via 531 is preferably arranged in such a manner as to penetrate the inside of the FTI structure 521. As a result, since a space of separately arranging the via 531 is unnecessary, the area of the effective pixels 310 can be further reduced.

### Eighth Modification Example

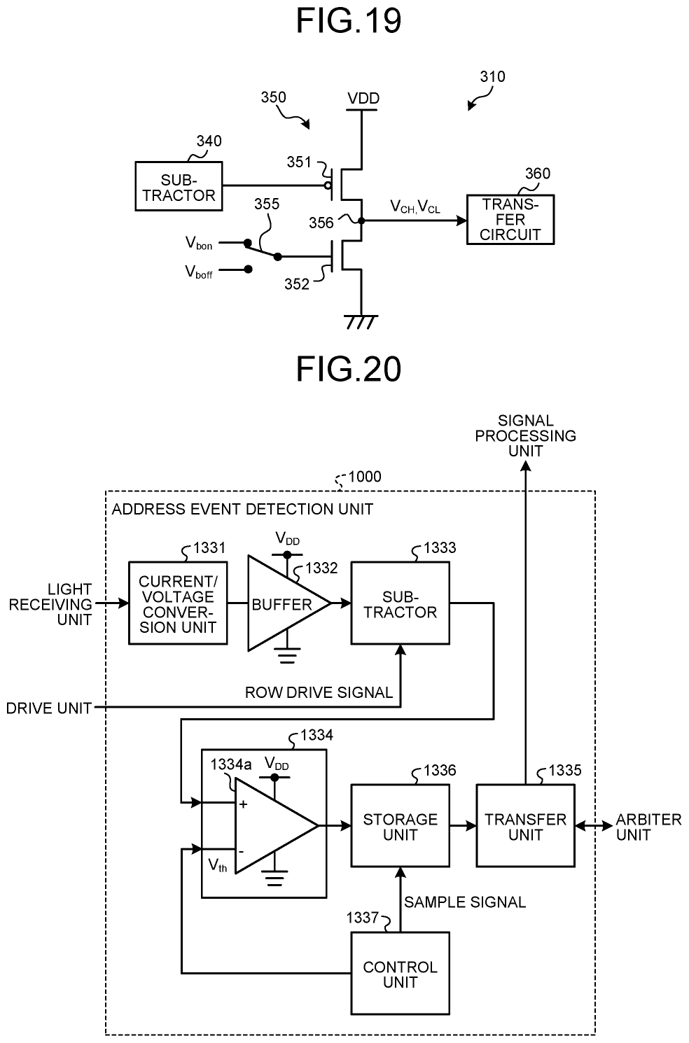

FIG. 19 is a view illustrating a circuit configuration of an effective pixel 310 according to the eighth modification example of the embodiment of the present disclosure, and illustrating a quantizer 350 that detects presence or absence of any one of a selected on-event or off-event.

The quantizer 350 according to the eighth modification example includes a P-type transistor 351, an N-type transistor 352, and a switch 355. The P-type transistor 351 and the N-type transistor 352 are connected in series in this order between a terminal of a power supply voltage VDD and a terminal of ground potential.

Furthermore, a gate of the P-type transistor 351 is connected to an output terminal of a subtractor 340. A gate of the N-type transistor 352 is connected to the switch 355.

Then, the control unit 130 can apply a bias voltage V_{bon}, indicating an upper limit threshold or a bias voltage V_{boff} indicating a lower limit threshold to the gate of the N-type transistor 352 by switching the switch 355. A connection point 356 of the P-type transistor 351 and the N-type transistor 352 is connected to a transfer circuit 360.

Then, in a case where the bias voltage V_{bon} is applied to the gate of the N-type transistor 352, in the quantizer 350 according to the eighth modification example, a voltage at the connection point 356 is output to the transfer circuit 360 as an on-event detection signal V_{CH}.

On the other hand, in a case where the bias voltage V_{boff} is applied to the gate of the N-type transistor 352, in the quantizer 350 according to the eighth modification example, the voltage at the connection point 356 is output to the transfer circuit 360 as an off-event detection signal V_{CL}.

With such a configuration, the quantizer 350 according to the eighth modification example outputs the high-level on-event detection signal V_{CH} when a differential signal exceeds the upper limit threshold in a case where the on-event is selected by a control unit 130.

On the other hand, in a case where the off-event is selected by the control unit 130, the quantizer 350 according to the eighth modification example outputs the low-level off-event detection signal V_{CL} when the differential signal falls below the lower limit threshold.

For example, in the solid-state imaging element 200 according to the eighth modification example, when a light source (not illustrated) is turned on by a command from the control unit 130 or the like, the on-event detection signal V_{CH} can be efficiently output when the control unit 130 selects the on-event.

For example, in the solid-state imaging element 200 according to the eighth modification example, when the light source (not illustrated) is turned off by a command from the control unit 130 or the like, the off-event detection signal V_{CL} can be efficiently output when the control unit 130 selects the off-event.

In the eighth modification example described above, since the number of transistors included in the quantizer 350 can be reduced, a chip area of the solid-state imaging element 200 can be reduced, and power consumption of the solid-state imaging element 200 can be reduced.

[Effect]

The solid-state imaging element 200 according to an embodiment includes the light receiving substrate 201 and the circuit board 202. The light receiving substrate 201 includes the plurality of light receiving circuits 211 provided with the photoelectric conversion elements (photodiodes 311). The circuit board 202 is bonded to the light receiving substrate 201 and includes the plurality of address event detection circuits 231 that respectively detects voltage changes output from the photoelectric conversion elements (photodiodes 311) of the plurality of light receiving circuits 211. Furthermore, the circuit board 202 includes the first element region 501 and the second element region 502. In the first element region 501, the first transistor T1 driven by the first voltage VDD1 is arranged. In the second element region 502, the second transistor T2 driven by the second voltage VDD2 lower than the first voltage VDD1 is arranged. Then, the full trench isolation (FTI) structure 521 is arranged between the first element region 501 and the second element region 502 adjacent to each other.

As a result, the areas of the effective pixels 310 can be reduced.

Furthermore, in the solid-state imaging element 200 according to an embodiment, the end portion on the opposite side of the light incident side of the FTI structure 521 is in contact with the insulating layer 202c.

As a result, the areas of the effective pixels 310 can be further reduced.

Furthermore, in the solid-state imaging element 200 according to an embodiment, a part of the end portion on the opposite side of the light incident side of the FTI structure 521 is in contact with the insulating layer 202c.

As a result, the areas of the effective pixels 310 can be further reduced.

Furthermore, in the solid-state imaging element 200 according to an embodiment, the end portion on the opposite side of the light incident side of the FTI structure 521 is in contact with the well layer 202d of the conductivity type different from that of the first well region (N-well region 511) located in the first element region 501.

As a result, the areas of the effective pixels 310 can be further reduced.

Furthermore, in the solid-state imaging element 200 according to an embodiment, a part of the end portion on the opposite side of the light incident side of the FTI structure 521 is in contact with the well layer 202d.

As a result, the areas of the effective pixels 310 can be further reduced.

Furthermore, in the solid-state imaging element 200 according to an embodiment, the wiring lines of the light receiving substrate 201 and the circuit board 202 are directly bonded to each other.

As a result, resolution of the solid-state imaging element 200 can be improved.

Furthermore, in the solid-state imaging element 200 according to an embodiment, the wiring lines of the light receiving substrate 201 and the circuit board 202 are connected to each other by the via 531.

Thus, the process of bonding the light receiving substrate 201 and the circuit board 202 can be simplified.

Furthermore, in the solid-state imaging element 200 according to an embodiment, the second element region 502 includes the second well region of a first conductivity type (P-well region 512) and the third well region of a second conductivity type (N-well region 513). In addition, another FTI structure 523 is arranged between the second well region (P-well region 512) and the third well region (N-well region 513) adjacent to each other.

As a result, it is possible to further control deterioration in the signal quality of the address event detection circuit 231 due to noise caused by disturbance or the like.

### Second Configuration Example of an Address Event Detection Unit

FIG. 20 is a block diagram illustrating a second configuration example of an address event detection unit 1000. As illustrated in FIG. 20, the address event detection unit 1000 according to the present configuration example includes a storage unit 1336 and a control unit 1337 in addition to a current/voltage conversion unit 1331, a buffer 1332, a subtractor 1333, a quantizer 1334, and a transfer unit 1335.

The storage unit 1336 is provided between the quantizer 1334 and the transfer unit 1335, and accumulates an output of the quantizer 1334, that is, a comparison result of a comparator 1334a on the basis of a sample signal supplied from the control unit 1337. The storage unit 1336 may be a sampling circuit of a switch, plastic, capacity, or the like, or may be a digital memory circuit such as a latch or a flip-flop.

The control unit 1337 supplies a predetermined threshold voltage Vth to an inverting (−) input terminal of the comparator 1334a. The threshold voltage Vth supplied from the control unit 1337 to the comparator 1334a may have different voltage values among time divisions. For example, the control unit 1337 supplies a threshold voltage Vth1 corresponding to an on-event indicating that a change amount of a photocurrent exceeds an upper limit threshold and a threshold voltage Vth2 corresponding to an off-event indicating that the change amount falls below a lower limit threshold at different timings, whereby the one comparator 1334a can detect a plurality of types of address events.

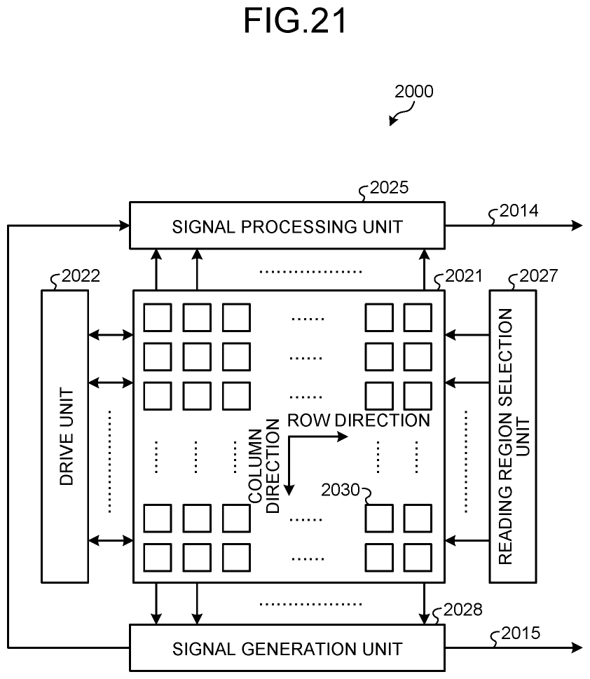

For example, the storage unit 1336 may accumulate the comparison result of the comparator 1334a using the threshold voltage Vth1 corresponding to the on-event in a period in which the threshold voltage Vth2 corresponding to the off-event is supplied from the control unit 1337 to the inverting (−) input terminal of the comparator 1334a. Note that the storage unit 1336 may be inside a pixel 2030 (see FIG. 21) or outside the pixel 2030. In addition, the storage unit 1336 is not an essential component of the address event detection unit 1000. That is, the storage unit 1336 may be omitted.

### Imaging Device (Scanning Method) According to the Second Configuration Example

The imaging device 100 according to the first configuration example described above is an asynchronous imaging device that reads an event by an asynchronous reading method. However, an event reading method is not limited to the asynchronous reading method, and may be a synchronous reading method. An imaging device to which the synchronous reading method is applied is an imaging device of a scanning method, the imaging device being the same as a normal imaging device that performs imaging at a predetermined frame rate.

FIG. 21 is a block diagram illustrating an example of a configuration of an imaging device according to the second configuration example, that is, the scanning type imaging device used as an imaging device 2000 in an imaging system to which the technology according to the present disclosure is applied.

As illustrated in FIG. 21, the imaging device 2000 that is according to the second configuration example and is as the imaging device of the present disclosure includes a pixel array unit 2021, a drive unit 2022, a signal processing unit 2025, a reading region selection unit 2027, and a signal generation unit 2028.

The pixel array unit 2021 includes a plurality of the pixels 2030. The plurality of pixels 2030 outputs an output signal in response to a selection signal of the reading region selection unit 2027. Each of the plurality of pixels 2030 may have a quantizer comparator in the pixel. The plurality of pixels 2030 outputs an output signal corresponding to a change amount in intensity of light. The plurality of pixels 2030 may be two-dimensionally arranged in a matrix as illustrated in FIG. 21.

The drive unit 2022 drives each of the plurality of pixels 2030 to output, to the signal processing unit 2025, a pixel signal generated in each of the pixels 2030. Note that the drive unit 2022 and the signal processing unit 2025 are circuit units to acquire gradation information. Thus, in a case where only event information is acquired, the drive unit 2022 and the signal processing unit 2025 may be omitted.

The reading region selection unit 2027 selects some of the plurality of pixels 2030 included in the pixel array unit 2021. Specifically, the reading region selection unit 2027 determines a selection region in response to a request from each of the pixels 2030 of the pixel array unit 2021. For example, the reading region selection unit 2027 selects any one or a plurality of rows among the rows included in the structure of the two-dimensional matrix corresponding to the pixel array unit 2021. The reading region selection unit 2027 sequentially selects one or a plurality of rows according to a preset cycle. Furthermore, the reading region selection unit 2027 may determine the selection region in response to the request from each of the pixels 2030 of the pixel array unit 2021.

On the basis of the output signal of the pixel selected by the reading region selection unit 2027, the signal generation unit 2028 generates an event signal corresponding to an active pixel in which an event is detected among the selected pixels. The event is an event in which the intensity of light changes. The active pixel is a pixel in which a change amount in the intensity of light corresponding to the output signal exceeds or falls below a preset threshold. For example, the signal generation unit 2028 compares the output signal of each of the pixels with a reference signal, detects an active pixel that outputs the output signal in a case where the output signal is larger or smaller than the reference signal, and generates an event signal corresponding to the active pixel.

The signal generation unit 2028 can include, for example, a column selection circuit that arbitrates a signal entering the signal generation unit 2028. Furthermore, the signal generation unit 2028 can be configured to output not only the information of the active pixel in which the event is detected but also the information of an inactive pixel in which the event is not detected.

Address information and time stamp information (such as (X, Y, T)) of the active pixel in which the event is detected are output from the signal generation unit 2028 through an output line 2015. However, data output from the signal generation unit 2028 may be not only the address information and the time stamp information but also information in a frame format (such as (0, 0, 1, 0, . . . )).

[Ranging System]

A ranging system according to an embodiment of the present disclosure is a system to measure a distance to a subject by using a technology of a structured light method. Furthermore, the ranging system according to the embodiment of the present disclosure can also be used as a system that acquires a three-dimensional (3D) image, and can be referred to as a three-dimensional image acquisition system in this case. In the structured light method, distance measurement is performed by identification of coordinates of a point image and a light source from which the point image is projected (so-called point light source) by pattern matching.

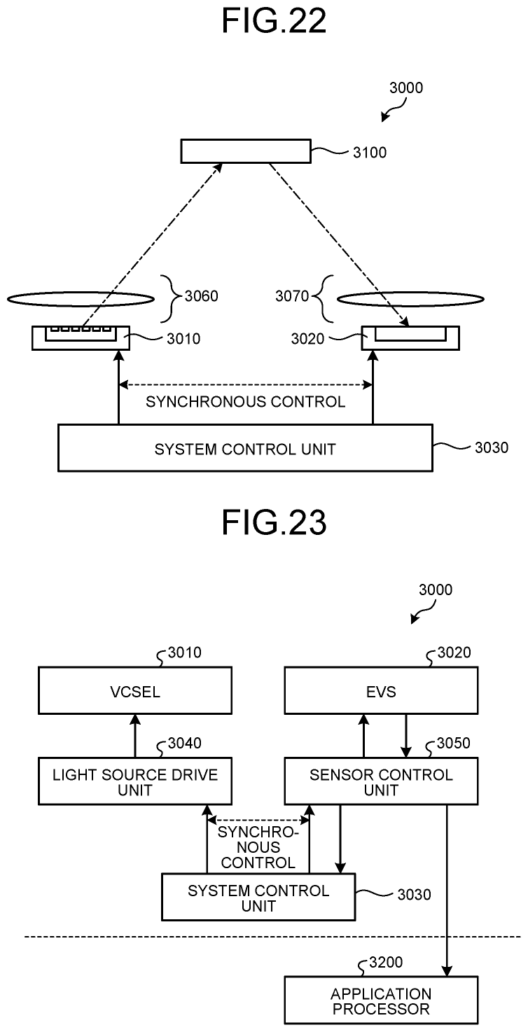

FIG. 22 is a schematic diagram illustrating an example of a configuration of the ranging system according to the embodiment of the present disclosure, and FIG. 23 is a block diagram illustrating an example of a circuit configuration.

A ranging system 3000 according to the present embodiment uses a surface emitting semiconductor laser such as a vertical cavity surface emitting laser (VCSEL) 3010 as a light source unit, and uses an event detection sensor 3020 called EVS as a light receiving unit. The vertical cavity surface emitting laser (VCSEL) 3010 projects a predetermined pattern of light onto a subject 3100. The ranging system 3000 according to the present embodiment includes a system control unit 3030, a light source drive unit 3040, a sensor control unit 3050, a light source-side optical system 3060, and a camera-side optical system 3070 in addition to the vertical cavity surface emitting laser 3010 and the event detection sensor 3020.

The system control unit 3030 includes, for example, a processor (CPU), drives the vertical cavity surface emitting laser 3010 via the light source drive unit 3040, and drives the event detection sensor 3020 via the sensor control unit 3050. More specifically, the system control unit 3030 synchronously controls the vertical cavity surface emitting laser 3010 and the event detection sensor 3020.

In the ranging system 3000 according to the present embodiment having the above configuration, the predetermined pattern of light emitted from the vertical cavity surface emitting laser 3010 is projected onto the subject (measurement target) 3100 through the light source-side optical system 3060. The projected light is reflected on the subject 3100. Then, the light reflected on the subject 3100 becomes incident on the event detection sensor 3020 through the camera-side optical system 3070. The event detection sensor 3020 receives the light reflected on the subject 3100, and detects, as an event, that a luminance change in the pixel exceeds a predetermined threshold. The event information detected by the event detection sensor 3020 is supplied to an application processor 3200 outside the ranging system 3000. The application processor 3200 performs predetermined processing on the event information detected by the event detection sensor 3020.

Although embodiments of the present disclosure have been described above, the technical scope of the present disclosure is not limited to the above-described embodiments as they are, and various modifications can be made within the spirit and scope of the present disclosure. In addition, components of different embodiments and modification examples may be arbitrarily combined.

Furthermore, an effect described in the present description is merely an example and is not a limitation, and there may be another effect.

Note that the present technology can also have the following configurations.

(1)

A solid-state imaging element comprising:
a light receiving substrate including a plurality of light receiving circuits provided with photoelectric conversion elements; and
a circuit board that is bonded to the light receiving substrate and includes a plurality of address event detection circuits that respectively detects voltage changes output from the photoelectric conversion elements of the plurality of light receiving circuits, wherein
the circuit board includes
a first element region in which a first transistor driven by a first voltage is arranged, and
a second element region in which a second transistor driven by a second voltage lower than the first voltage is arranged, and
a full trench isolation (FTI) structure is arranged between the first element region and the second element region adjacent to each other.

(2)

The solid-state imaging element according to the above (1), wherein
an end portion on an opposite side of a light incident side of the FTI structure is in contact with an insulating layer.

(3)

The solid-state imaging element according to the above (2), wherein
a part of the end portion on the opposite side of the light incident side of the FTI structure is in contact with the insulating layer.

(4)

The solid-state imaging element according to the above (1), wherein
an end portion on an opposite side of a light incident side of the FTI structure is in contact with a well layer of a conductivity type different from that of a first well region located in the first element region.

(5)

The solid-state imaging element according to the above (4), wherein
a part of the end portion on the opposite side of the light incident side of the FTI structure is in contact with the well layer.

(6)

The solid-state imaging element according to any one of the above (1) to (5), wherein
wiring lines of the light receiving substrate and the circuit board are directly bonded to each other.

(7)

The solid-state imaging element according to any one of the above (1) to (5), wherein
wiring lines of the light receiving substrate and the circuit board are connected to each other by a via.

(8)

The solid-state imaging element according to any one of the above (1) to (7), wherein
the second element region includes a second well region of a first conductivity type and a third well region of a second conductivity type, and
another FTI structure is arranged between the second well region and the third well region adjacent to each other.

(9)

An imaging device comprising:
a lens;
a solid-state imaging element; and
a control unit that controls the solid-state imaging element, wherein
the solid-state imaging element includes
a light receiving substrate including a plurality of light receiving circuits provided with photoelectric conversion elements,
a circuit board that is bonded to the light receiving substrate and includes a plurality of address event detection circuits that respectively detects voltage changes output from the photoelectric conversion elements of the plurality of light receiving circuits, and
a signal processing unit that performs signal processing on an output of the solid-state imaging element,
the circuit board includes
a first element region in which a first transistor driven by a first voltage is arranged, and
a second element region in which a second transistor driven by a second voltage lower than the first voltage is arranged, and
a full trench isolation (FTI) structure is arranged between the first element region and the second element region adjacent to each other.

(10)

The imaging device according to the above (9), in which an end portion on an opposite side of a light incident side of the FTI structure is in contact with an insulating layer.

(11)

The imaging device according to the above (10), in which
a part of the end portion on the opposite side of the light incident side of the FTI structure is in contact with the insulating layer.

(12)

The imaging device according to the above (9), in which
an end portion on an opposite side of a light incident side of the FTI structure is in contact with a well layer of a conductivity type different from that of a first well region located in the first element region.

(13)

The imaging device according to the above (12), in which
a part of the end portion on the opposite side of the light incident side of the FTI structure is in contact with the well layer.

(14)

The imaging device according to any one of the above (9) to (13), in which
wiring lines of the light receiving substrate and the circuit board are directly bonded to each other.

(15)

The imaging device according to any one of the above (9) to (13), in which
wiring lines of the light receiving substrate and the circuit board are connected to each other by a via.

(16)

The imaging device according to any one of the above (9) to (15), in which
the second element region includes a second well region of a first conductivity type, and a third well region of a second conductivity type, and
another FTI structure is arranged between the second well region and the third well region adjacent to each other.

### REFERENCE SIGNS LIST

100 IMAGING DEVICE
110 LENS
130 CONTROL UNIT
200 SOLID-STATE IMAGING ELEMENT
201 LIGHT RECEIVING SUBSTRATE
202 CIRCUIT BOARD
202b SEMICONDUCTOR LAYER
202c INSULATING LAYER
211 LIGHT RECEIVING CIRCUIT
231 ADDRESS EVENT DETECTION CIRCUIT
310 EFFECTIVE PIXEL
311 PHOTODIODE (EXAMPLE OF PHOTOELECTRIC CONVERSION ELEMENT)
501 FIRST ELEMENT REGION
502 SECOND ELEMENT REGION
511 N-WELL REGION (EXAMPLE OF FIRST WELL REGION)
512 P-WELL REGION (EXAMPLE OF SECOND WELL REGION)
513 N-WELL REGION (EXAMPLE OF THIRD WELL REGION)
521, 523 FTI STRUCTURE
522 STI STRUCTURE
531 VIA
T1 FIRST TRANSISTOR
T2 SECOND TRANSISTOR
VDD1 FIRST VOLTAGE
VDD2 SECOND VOLTAGE

1. A solid-state imaging element comprising:
a light receiving substrate including a plurality of light receiving circuits provided with photoelectric conversion elements; and
a circuit board that is bonded to the light receiving substrate and includes a plurality of address event detection circuits that respectively detects voltage changes output from the photoelectric conversion elements of the plurality of light receiving circuits, wherein
the circuit board includes
a first element region in which a first transistor driven by a first voltage is arranged, and
a second element region in which a second transistor driven by a second voltage lower than the first voltage is arranged, and
a full trench isolation (FTI) structure is arranged between the first element region and the second element region adjacent to each other.

2. The solid-state imaging element according to claim 1, wherein
an end portion on an opposite side of a light incident side of the FTI structure is in contact with an insulating layer.

3. The solid-state imaging element according to claim 2, wherein
a part of the end portion on the opposite side of the light incident side of the FTI structure is in contact with the insulating layer.

4. The solid-state imaging element according to claim 1, wherein
an end portion on an opposite side of a light incident side of the FTI structure is in contact with a well layer of a conductivity type different from that of a first well region located in the first element region.

5. The solid-state imaging element according to claim 4, wherein
a part of the end portion on the opposite side of the light incident side of the FTI structure is in contact with the well layer.

6. The solid-state imaging element according to claim 1, wherein
wiring lines of the light receiving substrate and the circuit board are directly bonded to each other.

7. The solid-state imaging element according to claim 1, wherein
wiring lines of the light receiving substrate and the circuit board are connected to each other by a via.

8. The solid-state imaging element according to claim 1, wherein
the second element region includes a second well region of a first conductivity type and a third well region of a second conductivity type, and
another FTI structure is arranged between the second well region and the third well region adjacent to each other.

9. An imaging device comprising:
a lens;
a solid-state imaging element; and
a control unit that controls the solid-state imaging element, wherein
the solid-state imaging element includes
a light receiving substrate including a plurality of light receiving circuits provided with photoelectric conversion elements,
a circuit board that is bonded to the light receiving substrate and includes a plurality of address event detection circuits that respectively detects voltage changes output from the photoelectric conversion elements of the plurality of light receiving circuits, and
a signal processing unit that performs signal processing on an output of the solid-state imaging element,
the circuit board includes
a first element region in which a first transistor driven by a first voltage is arranged, and
a second element region in which a second transistor driven by a second voltage lower than the first voltage is arranged, and
a full trench isolation (FTI) structure is arranged between the first element region and the second element region adjacent to each other.
